(19) United States
(12) Patent Application Publication
(10) Pub. No.: US 2024/0287679 A1
(43) Pub. Date: Aug. 29, 2024

(54) WAFER PROCESSING APPARATUS WITH FILM UNIFORMITY IMPROVEMENT CAPABILITIES

(71) Applicant: ASM IP Holding B.V., Almere (NL)

(72) Inventors: Yongjin Jeong, Seongnam-si (KR); Naoto Tsuji, Tokyo (JP); ByeongPil Park, Hwaseong-si (KR); Yonjong Jeon, Yongin-si (KR)

(21) Appl. No.: 18/585,313

(22) Filed: Feb. 23, 2024

Related U.S. Application Data
(60) Provisional application No. 63/448,914, filed on Feb. 28, 2023.

(51) Int. Cl. C23C 16/46; H01L 21/67

(52) U.S. Cl. CPC C23C 16/46; H01L 21/67109

(57) ABSTRACT

A wafer processing apparatus may be presented. The apparatus may comprise a wafer support provided with a heater for supporting and heating the wafer, a chamber for enclosing and processing the wafer, a showerhead for letting gas in the chamber, a pumping port for removing gas from the chamber, a black wall with a substantially high emissivity provided to the chamber near the pumping port and configured to partly encircle the wafer support; and a white wall with a substantially low emissivity provided to the chamber on opposite side of the pumping port and configured to partly encircle the wafer support.

### CROSS-REFERENCE TO RELATED APPLICATIONS

This application claims priority to U.S. Provisional Patent Application Ser. No. 63/448,914 filed Feb. 28, 2023 titled WAFER PROCESSING APPARATUS WITH FILM UNIFORMITY IMPROVEMENT CAPABILITIES, the disclosure of which is hereby incorporated by reference in its entirety.

### FIELD OF INVENTION

The present disclosure relates to a wafer processing apparatus, particularly to an apparatus equipped with capabilities to improve film uniformity.

### BACKGROUND OF THE DISCLOSURE

In a film deposition apparatus, a heater in a reaction chamber is used to heat a wafer up to a reaction temperature and also maintain the temperature constantly throughout the process. This temperature uniformity is one of the key parameters of the wafer process result.

Conventionally, the heater would have multiple heating and/or cooling zones to keep the temperature map of the wafer to be uniform. But this method is very expensive and complex to implement.

Usually, the heated gas used for processing a wafer is exiting through a pumping port so the part of the wafer near the pumping port is heated more than the other parts of the wafer.

Therefore, the present disclosure presents an apparatus with an improved wafer uniformity by controlling temperature uniformity.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a wafer processing apparatus, comprising: a wafer support provided with a heater for supporting and heating a wafer; a chamber for enclosing and processing the wafer; a showerhead for providing a gas into the chamber; a pumping port for removing the gas from the chamber; a black wall with a substantially high emissivity provided to the chamber near the pumping port and configured to partly encircle the wafer support; and a white wall with a substantially low emissivity provided to the chamber on an opposite side of the pumping port and configured to partly encircle the wafer support.

In at least one aspect, the black wall comprises a plurality of black wall strips with a first predetermined width, and the white wall comprises a plurality of white wall strips with a second predetermined width, wherein each of the plurality of black wall strips and each of the plurality of white wall strips are removable.

In at least one aspect, the apparatus further comprising a wall path configured to encircle the wafer support fully or partially.

In at least one aspect, the black wall comprises a plurality of black wall strips, each of the plurality of black wall strips equipped with a bonding part which is used to connect it to a neighboring black wall strip; and the white wall comprises a plurality of white wall strips, each of the plurality of white wall strips equipped with a bonding part which is used to connect it to a neighboring white wall strip, and wherein the each of the black wall strips and each of the white wall strips configured to be placed on the wall path, and the each of the black wall strips and each of the white wall strips further configured to slide along the wall path between an expanded state and a contracted state.

In at least one aspect, the black wall comprises a first black plate and a second black plate; and the white wall comprises a first white plate and a second white plate, wherein the first black plate comprises a first area with a first emissivity lower than a first emissivity threshold and a second area with a second emissivity higher than a second emissivity threshold, the first area and the second area being alternately arranged by a predetermined interval and, the second black plate comprises a third area with a third emissivity higher than the second emissivity threshold and a slit, the third area and the slit being alternately arranged by the predetermined interval, and wherein the first white plate comprises a fourth area with a fourth emissivity lower than the first emissivity threshold and a fifth area with a fifth emissivity higher than the second emissivity threshold, the fourth area and the fifth area being alternately arranged by a preselected interval; and the second white plate comprises a sixth area with a sixth emissivity lower than the first emissivity threshold and a slit, the sixth area and the slit being alternately arranged by the preselected interval, wherein the first black plate and/or the second black plate configured to slide on the wall path sideways, and the first white plate and/or the second white plate configured to slide on the wall path sideways.

In at least one aspect, a plurality of first rotatable rails configured to be placed in a first partial wall path, and a plurality of black wall strips configured to be bound to the plurality of the first rotatable rails, and wherein the plurality of first rotatable rails configured to rotate in clockwise or counterclockwise direction to arrange the plurality of black wall strips into a state between an expanded state and a contracted state.

In at least one aspect, a plurality of second rotatable rails which are rotatable configured to be placed in a second partial wall path, a plurality of white wall strips configured to be bound to the plurality of the second rotatable rails, and wherein the plurality of second rotatable rails configured to rotate in clockwise or counterclockwise direction, respectively, to arrange the plurality of the white wall strips into a state between an expanded state and a contracted state.

In accordance with another embodiment there may be provided, a wafer processing apparatus, comprising: a wafer support provided with a heater for supporting and heating a wafer; a chamber for enclosing and processing the wafer; a showerhead for providing a gas into the chamber; a pumping port for removing the gas from the chamber; a black wall with a substantially high emissivity provided to the chamber near the pumping port and configured to partly encircle the wafer support; a white wall with a substantially low emissivity provided to the chamber on opposite side of the pumping port and configured to partly encircle the wafer support; a wall path configured to encircle the wafer support fully or partially; and a wall moving mechanism configured to move the black wall and the white wall along the wall path.

In at least one aspect, the apparatus further comprising: a linking material configured to link the wall moving mechanism and the black wall, and further configured to link the wall moving mechanism and the white wall.

In at least one aspect, the black wall comprises a plurality of black wall strips with a predetermined width, each of the plurality of black wall strips equipped with a bonding part which is used to connect it to a neighboring black wall strip; and the white wall comprises a plurality of white wall strips with another predetermined width, each of the plurality of white wall strips equipped with a bonding part which is used to connect it to a neighboring white wall strip, wherein the linking material comprises a plurality of linking members, wherein the plurality of linking members configured to link each of the plurality of black wall strips to the wall moving mechanism and further configured to link each of the plurality of the white wall strips to the wall moving mechanism, wherein the wall moving mechanism configured to pull and/or push the plurality of the linking members to arrange the plurality of the black wall strips and/or the plurality of the white wall strips into a state between an expanded state and a contracted state.

In at least one aspect, the black wall comprises a first black plate and a second black plate, and the white wall comprises a first white plate and a second white plate, wherein the first black plate comprises a first area with a first emissivity lower than a first emissivity threshold and a second area with a second emissivity higher than a second emissivity threshold, the first area and the second area being alternately arranged by a predetermined interval and, the second black plate comprises a third area with a third emissivity higher than the second emissivity threshold and a slit, the third area and the slit being alternately arranged by the predetermined interval, and wherein the first white plate comprises a fourth area with a fourth emissivity lower than the first emissivity threshold and a fifth area with a fifth emissivity higher than the second emissivity threshold, the fourth area and the fifth area being alternately arranged by a preselected interval; and the second white plate comprises a sixth area with a sixth emissivity lower than the first emissivity threshold and a slit, the sixth area and the slit being alternately arranged by the preselected interval, and wherein the linking material comprises four linking members, wherein each of the linking members are configured to link the wall moving mechanism and the first black plate, the second black plate, the first white plate and the second white plate, respectively, and wherein the wall moving mechanism configured to pull and/or push the linking members to arrange the first and second black plate and the first and second white plate to change total emissivity for each of the black wall and the white wall.

In at least one aspect, a plurality of first rotatable rails which are rotatable configured to be placed in a first partial wall path, and a plurality of black wall strips configured to be bound to the plurality of the first rotatable rails, and wherein the wall moving mechanism is further configured to rotate each of the plurality of the first rotatable rails in clockwise or counterclockwise direction, respectively, to arrange the black wall strips into a state between an expanded state and a contracted state.

In at least one aspect, a plurality of second rotatable rails which are rotatable configured to be placed in a second partial wall path, and a plurality of white wall strips configured to be bound to the plurality of the second rotatable rails, and wherein the wall moving mechanism is further configured to rotate each of the plurality of the second rotatable rails in clockwise or counterclockwise direction, respectively, to arrange the white wall strips into a state between an expanded state and a contracted state.

In accordance with another embodiment there may be provided, a wafer processing apparatus, comprising: a wafer support provided with a heater for supporting and heating a wafer; a chamber for enclosing and processing the wafer; a showerhead for providing a gas into the chamber; a pumping port for removing gas from the chamber; a black wall with a substantially high emissivity provided to the chamber near the pumping port and configured to partly encircle the wafer support; a white wall with a substantially low emissivity provided to the chamber on opposite side of the pumping port and configured to partly encircle the wafer support; a wall path configured to encircle the wafer support; a wall moving mechanism configured to move the black wall and the white wall along the wall path; and a controller configured to control the wall moving mechanism by at least one of a wired connection or a wireless connection.

In at least one aspect, the apparatus further comprising: a linking material configured to provide a link between the wall moving mechanism and the black wall and a link between the wall moving mechanism and the white wall.

In at least one aspect, the black wall comprises a plurality of black wall strips with a predetermined width, each of the plurality of black wall strips equipped with a bonding part which is used to connect it to a neighboring black wall strip; and the white wall comprises a plurality of white wall strips with another predetermined width, each of the plurality of white wall strips equipped with a bonding part which is used to connect it to a neighboring white wall strip, wherein the linking material comprises a plurality of linking members, and wherein the plurality of linking members configured to link each of the plurality of black wall strips to the wall moving mechanism and further configured to link each of the plurality of the white wall strips to the wall moving mechanism, and the controller configured to control the wall moving mechanism to pull and/or push the plurality of the linking members to arrange the plurality of the black wall strips and/or the plurality of the white wall strips into a state between an expanded state and a contracted state.

In at least one aspect, the black wall comprises a first black plate and a second black plate, and the white wall comprises a first white plate and a second white plate, and wherein the first black plate comprises a first area with a first emissivity lower than a first emissivity threshold and a second area with a second emissivity higher than a second emissivity threshold, the first area and the second area alternately arranged by a predetermined interval; the second black plate comprises a third area with a third emissivity higher than the second emissivity threshold and a slit, the third area and the slit alternately arranged by the predetermined interval; and the first white plate comprises a fourth area with a fourth emissivity lower than a first emissivity threshold and a fifth area with a fifth emissivity higher than a second emissivity threshold alternately arranged by a preselected interval; and the second white plate comprises a sixth area with a sixth emissivity lower than the first emissivity threshold and a slit, the sixth area and the slit alternately arranged by the preselected interval, and wherein the linking material comprises four linking members, wherein each of the linking members are configured to link the wall moving mechanism and the first black plate, the second black plate, the first white plate and the second white plate, respectively, and wherein the controller is further configured to control the wall moving mechanism to pull and/or push the linking members to arrange the first and second black plate and the first and second white plate to change total emissivity for each of the black wall and the white wall.

In at least one aspect, a plurality of first rotatable rails configured to be placed along a first partial wall path, and a plurality of black wall strips configured to be bound to the plurality of the first rotatable rails, and wherein the controller configured to control the wall moving mechanism to rotate each of the plurality of the first rotatable rails in clockwise or counterclockwise direction, respectively, to arrange the black wall strips into a state between an expanded state and a contracted state.

In at least one aspect, a plurality of second rotatable rails configured to be placed along a second partial wall path, and a plurality of white wall strips configured to be bound to the plurality of the second rotatable rails, and wherein the controller configured to control the wall moving mechanism to rotate each of the plurality of the second rotatable rails in clockwise or counterclockwise direction, respectively, to arrange the white wall strips into a state between an expanded state and a contracted state.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of the wafer processing apparatus according to an embodiment of the present disclosure.

FIG. 2 illustrates a more detailed overview seen above a reaction chamber showing black wall and white wall, wall path and a wall moving mechanism according to an embodiment of the present disclosure.

FIG. 3A illustrates an example of a black wall in this disclosure according to an embodiment of the present disclosure.

FIG. 3B illustrates an example of a black wall comprising multiple strips according to another embodiment of the present disclosure.

FIG. 3C illustrates an example of a white wall in this disclosure according to an embodiment of the present disclosure.

FIG. 3D illustrates an example of a white wall comprising multiple strips according to another embodiment of the present disclosure.

FIG. 4A illustrates an example of black (or white) wall with multiple strips connected with bonding part according to another embodiment of the present disclosure.

FIG. 4B illustrates an example of black (or white) wall with multiple strips connected with bonding part when it is overlapped according to another embodiment of the present disclosure.

FIG. 5A illustrates a first white plate according to another embodiment of the present disclosure.

FIG. 5B illustrates a second white plate according to another embodiment of the present disclosure.

FIG. 5C illustrates a white wall with the first white plate and the second white plate positioned so that the white wall has minimum emissivity according to another embodiment of the present disclosure.

FIG. 5D illustrates a white wall with the first white plate and the second white plate positioned so that the white wall has somewhat medium emissivity according to an embodiment of the present disclosure. The first white plate and/or the second white plate slid to be overlapped with each other.

FIG. 5E illustrates a white wall with the first white plate and the second white plate positioned so that the white wall has maximum emissivity according to another embodiment of the present disclosure. The first white plate and/or the second white plate slid to be overlapped.

FIG. 6A illustrates a first black plate according to another embodiment of the present disclosure.

FIG. 6B illustrates a second black plate according to another embodiment of the present disclosure.

FIG. 6C illustrates a black wall with the first black plate and the second black plate positioned so that the black wall has minimum emissivity according to another embodiment of the present disclosure.

FIG. 6D illustrates a black wall with the first black plate and the second black plate positioned so that the black wall has somewhat medium emissivity according to another embodiment of the present disclosure. The first black plate and/or the second black plate slid to be overlapped with each other.

FIG. 6E illustrates a black wall with the first black plate and the second black plate positioned so that the black wall has maximum emissivity according to another embodiment of the present disclosure. The first black plate and/or the second black plate slid to be overlapped with each other.

FIG. 7 illustrates an example of the apparatus' front view according to an embodiment of the present disclosure.

FIG. 8A illustrates a reference setting of a test with no black wall and no white wall.

FIG. 8B illustrates a test setting compared to the FIG. 8A with a black wall with 45 degrees encirclement.

FIG. 8C illustrates a test setting compared to the FIG. 8A with a black wall with 90 degrees encirclement.

FIG. 9A illustrates a 5-strips black wall in a spaced-out (expanded) state with a bonding member placed in the middle of the each of the strips.

FIG. 9B illustrates how much the 5-strips black wall of FIG. 9A can be contracted (overlapped).

FIG. 9C illustrates a 5-strips black wall in a spaced-out state with a bonding member placed in the two thirds from the left of each of the strips.

FIG. 9D illustrates how much the 5-strips black wall of FIG. 9C can be contracted (overlapped).

FIG. 9E illustrates a 5-strips black wall in a spaced-out state with a bonding member placed in the three fourths from the left of each of the strips.

FIG. 9F illustrates how much the 5-strips black wall of FIG. 9E can be contracted (overlapped).

FIG. 10A illustrates another mode for spaced-out (expanded) state of strips according to another embodiment of the present disclosure.

FIG. 10B illustrates another mode for contracted (overlapped) state of strips according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

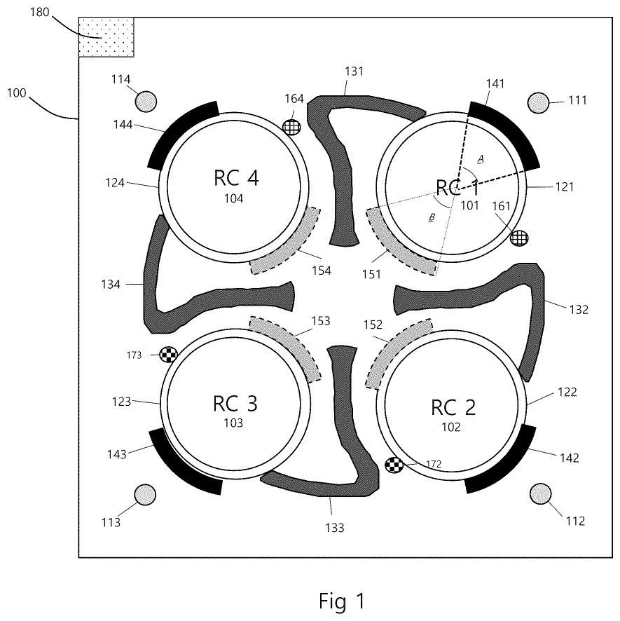

A wafer processing apparatus 100 with four (4) reaction chambers is illustrated according to an embodiment of this disclosure in FIG. 1 and showerheads above the reaction chambers are omitted for convenience.

In FIG. 1, four (4) identical chambers may be rectangularly arranged, but the number of chambers may be changed arbitrarily.

In a reaction chamber 101, there may be a wafer support 121 for heating and maintaining the reaction temperature for processing wafers. An arm 131 may be placed beside the reaction chamber 101 and it may be used for moving wafers onto the wafer support 121 and for removing wafers from the wafer support 121.

The apparatus 100 may have four (4) pumping ports in the four (4) corner regions so a pumping port 111 may be placed on the up-right corner of the chamber 101.

The wafer support 121 may emit heat during process for heating the wafer and maintains the reaction temperature during the process. For example, the reaction temperature may be more than 400° C.

The heat uniformity may be essential to the wafer film deposition uniformity. However, due to the position of the pumping port 111, the heated process gas may remain longer in the area around the pumping port 111 and its vicinity than other areas. This means the area of up right of the wafer placed on the wafer support 121 may be hotter than the other area of the wafer.

For controlling the temperature disparity on the wafer, a black wall 141 may be placed in the pumping port 111 direction (near to the pumping port 111). This black wall 141 may have substantially high emissivity (ε1) so that it may absorb heat more than it may emit.

By placing the black wall 141, the heat in the up-right area of the wafer on the wafer support 121 may be reduced more rapidly than the other areas of the wafer, enabling the wafer to have heat uniformity and therefore attaining wafer deposition uniformity.

At times, the heat disparity in the wafer may be more drastic so that merely placing the black wall 141 in line with the pumping port 111 would not be sufficient to attain the heat uniformity.

In this case, a white wall 151 may be placed on the opposite side of the black wall 141 as shown in FIG. 1.

This white wall 151 may have substantially low emissivity (ε2) so that it may emit heat more than it may absorb. Both the black wall 141 and the white wall 151 may be placed to partly encircle the wafer support 121 with some predetermined distance. Above descriptions for the reaction chamber 1 (101) also apply to the reaction chambers 2, 3, 4 (102, 103, 104).

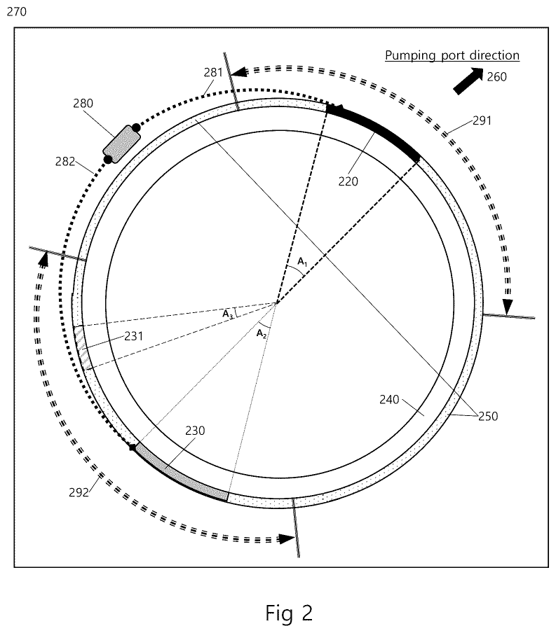

In FIG. 2, a chamber 1 (270) is illustrated in more detail.

The direction of a pumping port 260 is up-right of the chamber 270 and a black wall 220 is installed in this direction along a wafer support 240.

The black wall 220 and a white wall 230 may be installed to partly encircle the wafer support 240. And a wall path 250 may encircle the wafer support 240.

The wall path 250 may encircle the wafer support 240 fully or partially (291, 292). A partially encircling wall path would mean there may be two (2) separate partial wall paths (291, 292) each of them partially encircles the wafer support 240 as shown in FIG. 2.

However, the area (220) around the pumping port 260 may not be the area of higher temperature due to the structural characteristics of a processing apparatus or a reaction chamber. Also, the opposite area (230) across the wafer support 121 from the area of the pumping port 260 may not be the area of lower temperature with the same reason.

Therefore, the black wall 220 and the white wall 230 may be placed at the area where the temperature may be relatively higher (black wall) compared to the other areas or relatively lower (white wall) compared to the other areas, respectively, in general. However, in this disclosure, near the pumping port may be the area with higher temperature and opposite area of the pumping port across the wafer support may be the area with lower temperature for simple and easy explanation.

The wall path 250 may be a pathway on which the black wall 220 and the white wall 230 may be installed. The wall path 250 may be many shapes such as a trench shape or a railing way shape.

In an alternative embodiment, the black wall 220 and the white wall 230 could be installed without the wall path 250.

When the black wall 220 and the white wall 230 are installed on the wall path 250, they may be moved along the wall path 250.

If the wall path 250 may encircle the wafer support 240 fully, the black wall 220 or the white wall 230 can move along the wall path 250 until they meet. However, if the wall path 250 may partially encircle the wafer support 240 like the range 291 (black wall path) and the range 292 (white wall path) in FIG. 2, then the black wall 220 and the white wall 230 would have restricted area to move along (within 291 and 292, respectively).

The encircling angle of the black wall 220 is A1 while the angle is A2 for the white wall 230. The angles may be determined by the width of the black wall 220 and the white wall 230 therefore could be same or different due to the width difference.

For example, a white wall 231 has a width smaller than that of the white wall 230. So, the encirclement angle (A3) of the white wall 231 is smaller than that of the white wall 230.

The walls 220, 230 may be moved along the wall path 250 by a wall moving mechanism 280. The mechanism 280 is installed close to the wall path 250 and the mechanism 280 is connected with the black wall 220 and with the white wall 230, respectively, by a plurality of linking materials 281, 282.

The wall moving mechanism 280 could be placed anywhere as long as linking materials 281, 282 can connect the mechanism 280 to the black wall 220 and to the white wall 230, respectively. However, for operational efficiency, the wall moving mechanism 280 may better be placed in an area where the distance between the mechanism 280 and the black wall 220 (or the length of the linking material 281) may be similar to the distance between the mechanism 280 and the white wall 230 (or the length of the linking material 282).

As for the linking materials (281, 282), let's take the black wall 220 and its linking material 281 from the mechanism 280 for more description.

The linking material 281 from the mechanism 280 to the black wall 220 comprises one or more linking members connecting the mechanism 280 to each of the strips or plates of the black wall 220.

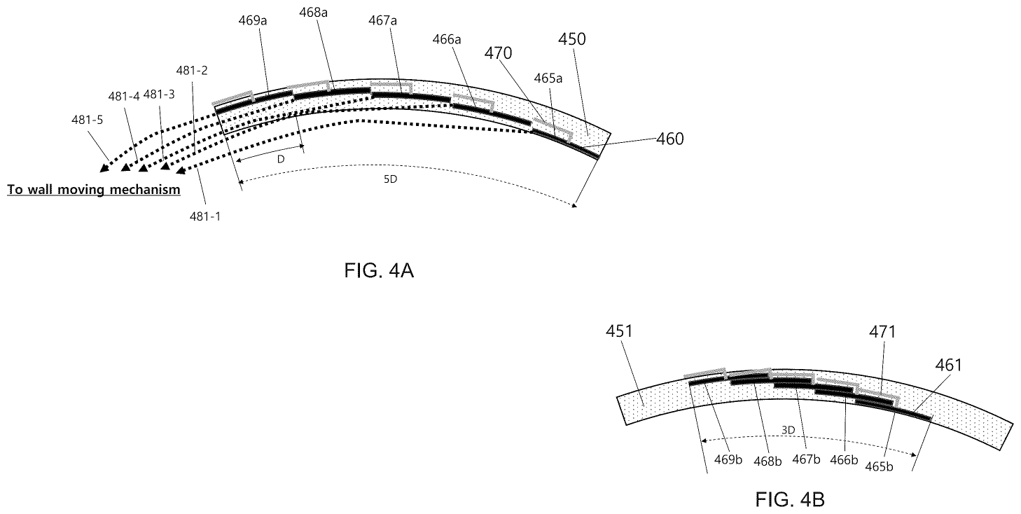

For example, when the black wall 460 comprises 5 strips (465a, 466a, 467a, 468a, 469a) as illustrated in FIG. 4A, the linking material 281, which connects the black wall 460 to the wall moving mechanism 280, may comprise 5 linking members (481-1, 481-2, 481-3, 481-4, 481-5) each of which connects the mechanism 280 to each one of the 5 strips (465a, 466a, 467a, 468a, 469a), respectively.

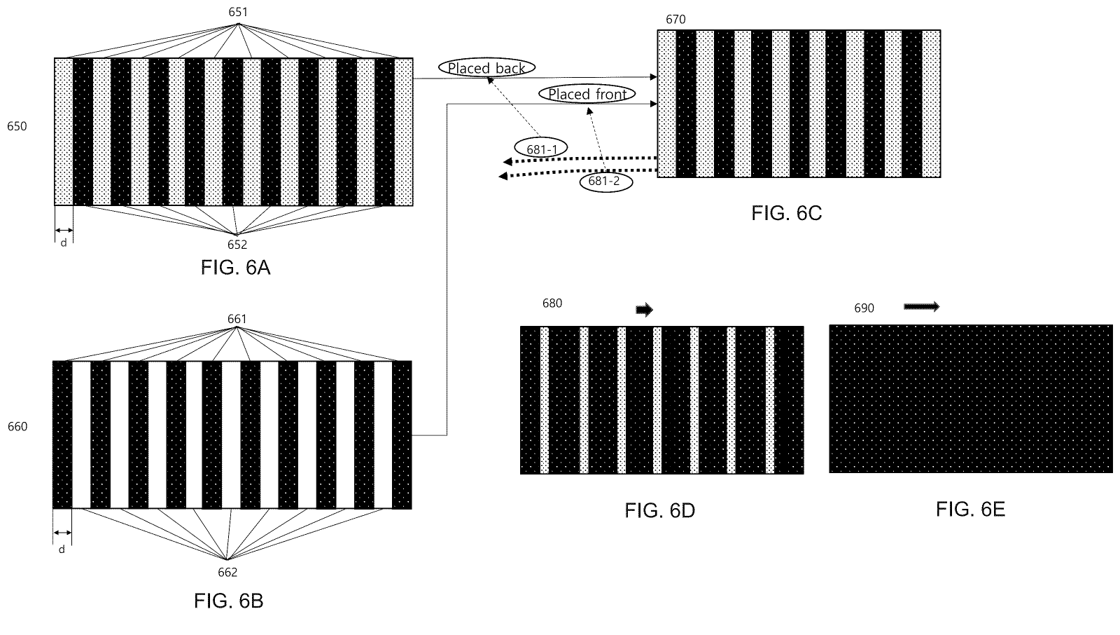

For another example, when the black wall 670 comprises 2 plates 650, 660 (first and second plate) as illustrated in FIG. 6C, the linking material 281, which connects the black wall 670 to the wall moving mechanism 280, comprises 2 linking members (681-1, 681-2) each of which connects the mechanism 280 to each of the 2 plates (650, 660), respectively.

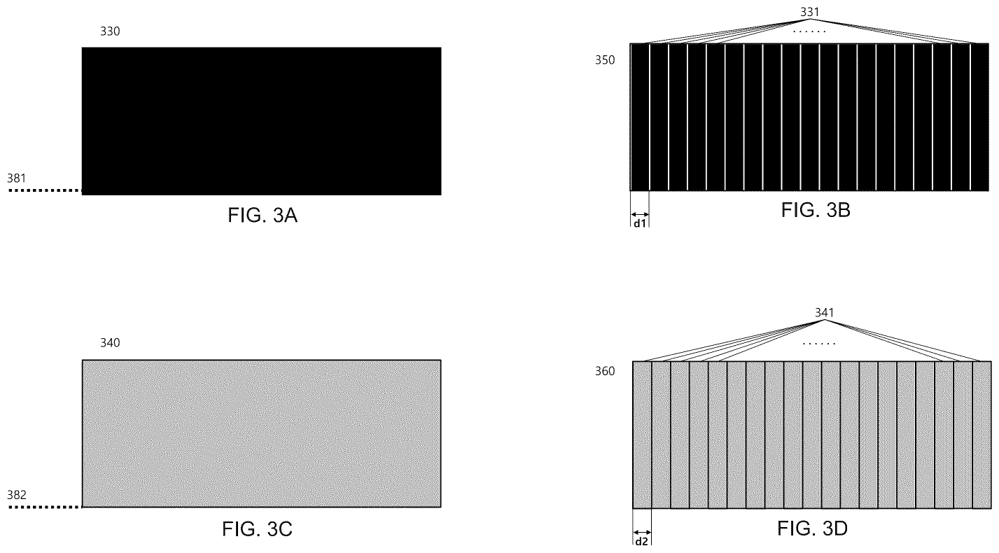

If the black wall 330 is a one continuous wall as illustrated in FIG. 3A, the linking material 381 may connect the black wall 330 to the wall moving mechanism 280 if the black wall 330 may be installed on a wall path.

Also, if the white wall 340 is a one continuous wall as illustrated in FIG. 3B, the linking material 382 may connect the white wall 340 the wall moving mechanism 280 if the black wall 330 may be installed on a wall path.

It should also be noted that the black wall 350, which comprises a multiple of removable strips, would not be connected to the mechanism 280 by linking materials since the strips may not be movable and they may be chipped off manually from the assembled wall 350 when the need arises.

With this setup, the mechanism 280 may move the walls 220, 230 by pushing or pulling the linking materials 281, 282. The linking materials 281, 282 can be steel wire or steel saw teeth line which may have a circular shape placed around the wall path 250 and they could be revealed or hidden at the bottom of the reaction chamber 270.

FIG. 3A and FIG. 3B illustrate two possible modes of a black wall 330. In FIG. 3A, the black wall 330 may be a continuous one rectangular shape while the black wall of FIG. 3B may comprise a series of small rectangular shapes 331 with a width d1.

Each of rectangular shapes 331 of a black wall 350 in FIG. 3B may be removed or a new rectangular shape with the width d1 or with an arbitrary width d2 may be added to the black wall 350 to change the effect of the black wall by changing the total width (therefore, the encirclement angle) of the resulting black wall 350.

FIG. 3C and FIG. 3D illustrate two possible modes of white walls. In FIG. 3C, a white wall 340 may be a continuous one rectangular shape while a white wall 360 of FIG. 3D may comprise a series of small rectangular shapes 341 with a width d2.

Each of the rectangular shapes 341 of the white wall 360 in FIG. 3D may be removed or a new rectangular shape with the width d2 may be added to the white wall 360 to change the effect of the white wall 360 by changing the total width (therefore, encirclement angle) of resulting white wall 360. The width of the newly added rectangular shape could be different from d2.

FIG. 4A illustrates an example of a black wall 460 in another embodiment of the present disclosure.

The black wall 460 may comprise a series of rectangular shapes 465a, 466a, 467a, 468a, 469a but each of the rectangular shapes has a bonding part which connects it to a neighboring rectangular shape.

In this example, the shape 465a is connected to the shape 466a by a bonding part 470, shape 466a to the shape 467a (bonding part not drawn), and so on. However, this connection sequence may be reversed. That means the shape 469a is connected to the shape 468a, the shape 468a to the shape 467a, and so on. (bonding parts not drawn).

The black wall 460 is placed on a wall path 450 but the shapes 465a, 466a, 467a, 468a, 469a are placed in a little skewed manner (spaced-out manner, expanded manner) as shown in FIG. 4A. When a black wall 461 is contracted, shapes 465b, 466b, 467b, 468b, 469b may be overlapped (overlapped manner or contracted manner) as shown in FIG. 4B.

FIG. 4B illustrates the contracted black wall 461 from the expanded status in FIG. 4A.

This overlapping of the shapes 465b, 466b, 467b, 468b, 469b may be done by the wall moving mechanism 280 explained above.

When the black wall 460 may be needed to have less total width than ‘5D’ in FIG. 4A, the wall moving mechanism 280 may execute pushing or pulling of the shapes with the linking materials 281, 282 as shown in FIG. 2 so that the total width of the resulting black wall 461 may be reduced to ‘3D’ as shown in FIG. 4B.

The bonding parts 470, 471 in this example may also restrict movement of parts. For example, in FIG. 4B the shape 466b is pushed into the position of shape 465b but the bonding part 471 blocks any further movement of the shape 466b.

In this example, the bonding parts 470, 471 are attached in a middle of each of the black wall shapes 465a, 466a, 467a, 468a, 469a, 465b, 466b, 467b, 468b, 469b of the black walls 460, 461. Therefore, the width of the black wall 460 can be reduced from 5D to 3D (the black wall 461) with 5 black wall shapes (strips), but the reduction ratio can be changed by changing the attaching position of the bonding parts of each of the shapes 465a, 466a, 467a, 468a, 469a.

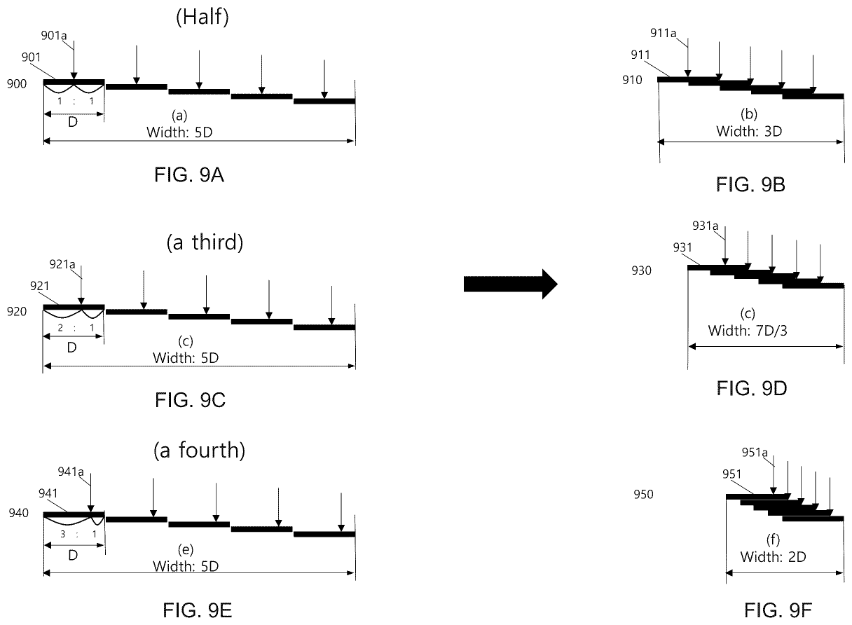

The resulting widths after contraction for each expanded black walls are illustrated in FIGS. 9A-9F.

In all cases, the width of a black wall strip (901, 921, 941) of each black wall (900, 920, 940) is ‘D’ and the total width of the black walls 900, 920, 940 is 5D with 5 strips as shown in FIGS. 9A-9F.

When a bonding part 901a is placed in the middle of a black wall strip 901 in a black wall 900 in an expanded (or spaced-out) status, the resulting width of a black wall 910 may be 3D down from 5D (shown in FIG. 9A and FIG. 9B).

If a bonding part 921a is placed in the position of a third from the right of a black wall strip 921 of a black wall 920 as in FIG. 9C, the resulting width of a black wall 930 could be 7D/3 down from 5D as shown in FIG. 9D.

If more contraction is needed, a bonding part 941a could be placed in the position of a fourth from the right of a black wall strip 941 in a black wall 940 as in FIG. 9E, the resulting width of a black wall 950 may be 2D down from 5D as shown in FIG. 9F.

The strip contraction (or in other words strip overlapping) explained in FIGS. 4A and 4B and FIGS. 9A-9F and the strip removal explained in FIG. 3B and FIG. 3D may have equal effect on heat uniformity, but strip removal would not be done during wafer process while strip contraction with wall movement mechanism 280 could be executed during wafer process. Therefore, strip contraction may be more flexible in maintaining heat uniformity.

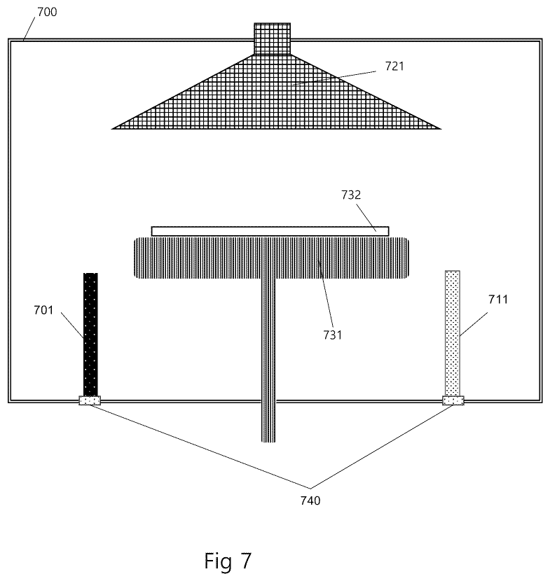

FIG. 7 illustrates the front view of an apparatus according to an embodiment of the present disclosure.

A wafer support 731 may support and heat a wafer 732 on it and a chamber 700 cases the wafer support 731 and the wafer support 731 may be placed in the center of the chamber 700. The showerhead 721 may provide the gas to the chamber 700 for processing the wafer 732 on the wafer support 731. An arm is not illustrated for convenience.

In the figure, a black wall 701 may be placed at the left while a white wall 711 may be placed at right of the chamber and both the black wall 701 and the white wall 711 may be placed on a wall path 740. It should be noted that the black wall 701 and white wall 711 are partly encircle around the wafer support 731 with a predetermined distance from it.

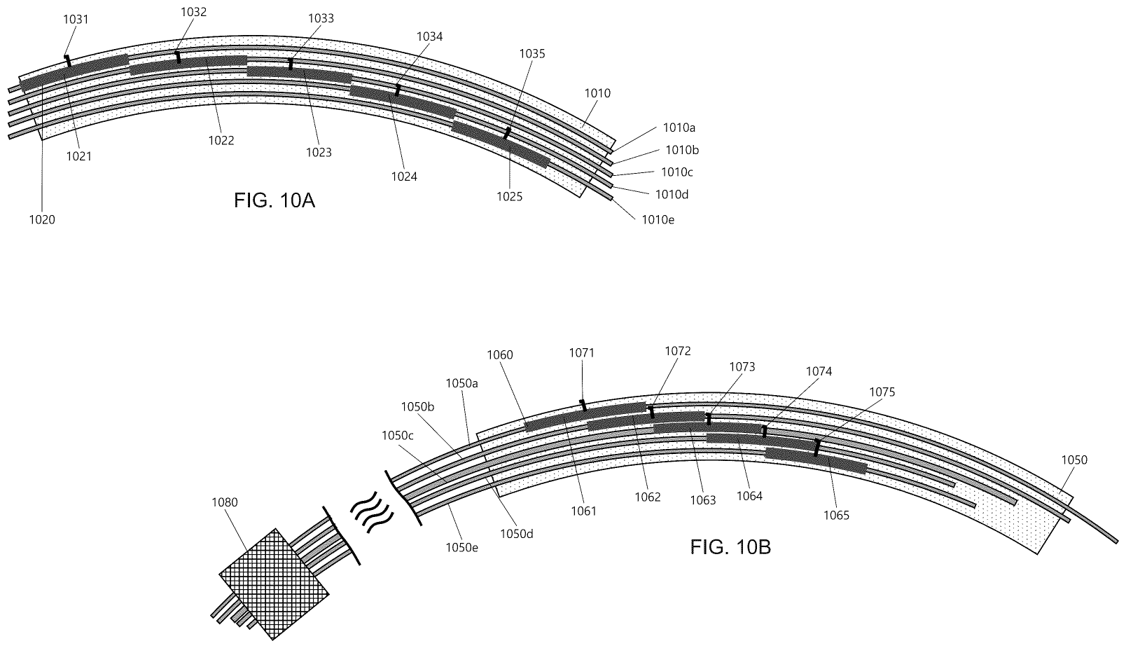

Another mode for the mechanism and the wall path may be illustrated in FIG. 10A and FIG. 10B. This embodiment would be used when the wall path for the black wall 220 and the white wall 230 partially surround (291, 292) the wafer support 240 just like in FIG. 2. For convenience, only black wall case is illustrated and explained but the same would be true for the white wall case.

In FIG. 10A, a wall path 1010 with 5 rails with a black wall 1020 with five (5) black wall strips (1021, 1022, 1023, 1024, 1025) in a spaced-out (expanded) status is illustrated.

There are 5 rails (1010a, 1010b, 1010c, 1010d, 1010e) in the wall path 1020. However, the number of rails in the wall path 1020 can vary.

The rails can slide sideways in their current positions along the circle they make. That means the rails can rotate in clockwise or counterclockwise direction. And the strips (1021, 1022, 1023, 1024, 1025) of the black wall 1020 may be removable from the attached positions but they may be constructed so that when they are bound to a specific position of a rail, they cannot move. It is the rotatable rails that can move so that the strips can move only when the rotatable rails they are bound to move.

FIG. 10B illustrates an example of a contracted status from the spaced-out (expanded) status of FIG. 10A. The rails (1010a, 1010b, 1010c, 1010d, 1010e) in FIG. 10A are stretched so that the wall movement mechanism 1080 holds the rails as shown in FIG. 10B.

The mechanism 1080 moves (i.e. rotates) the rails (1010a, 1010c, 1010d, 1010e) to make the black wall 1020 contracted as shown in FIG. 10B. In this example, the mechanism 1080 moves (rotates) the rail 1010a to a clockwise direction while the mechanism 1080 moves (rotates) the rails (1010c, 1010d, 1010e) to a counterclockwise direction. The rails rotate until the mechanism 1080 may dictate.

The stopping blocks (1031, 1032, 1033, 1034, 1035 & 1071, 1072, 1073, 1074, 1075) may be attached to each of the strips as shown in FIG. 10A and FIG. 10B. However, the stopping blocks may not be attached.

It also should be noted that the form of the black wall 701 could be one of the figures shown in \textcircled{1} FIG. 3A, \textcircled{2} FIG. 3B, \textcircled{3} FIG. 6A and FIG. 6B, \textcircled{4} FIG. 4A and \textcircled{5} FIG. 10A, and the form of the white wall 711 may be the same as those of the black wall just listed. The forms of the black wall 701 and the white wall 711 may be the same but they may be different from each other.

Please note that a pumping port is placed at the left side the black wall 701 even though it is not drawn in FIG. 7.

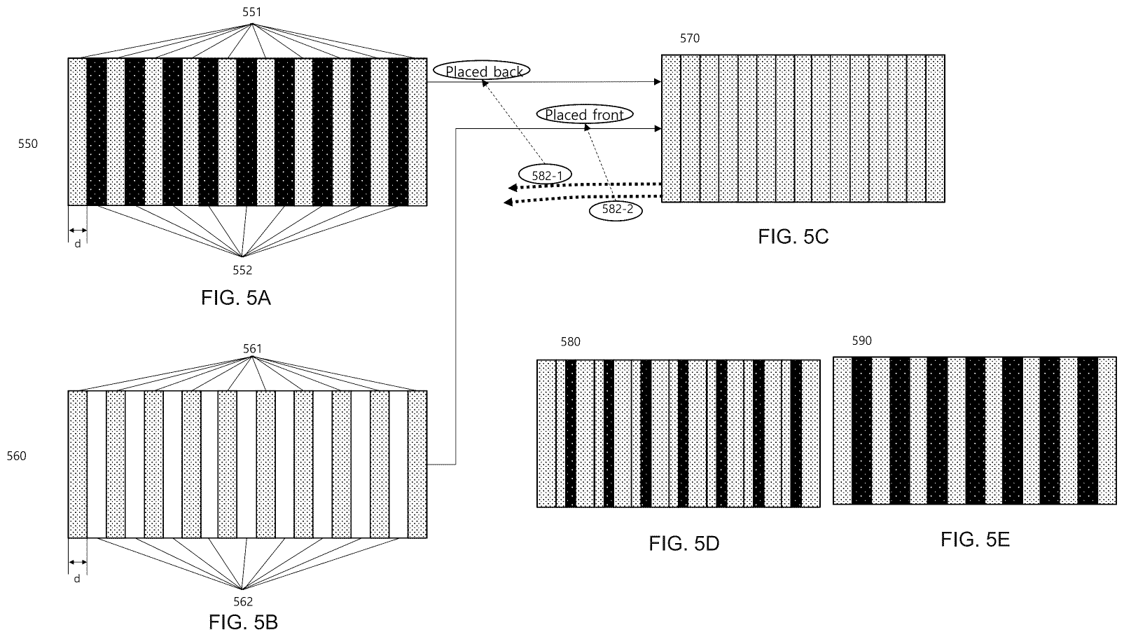

FIGS. 5A-5E and FIGS. 6A-6E illustrate a more flexible control of the emissivity of a black wall 141 and a white wall 151.

FIG. 5A illustrates a first white plate 550 and FIG. 5B illustrates a second white plate 560 according to another embodiment of this disclosure. The white wall 230 (in FIG. 2) may comprise the first white plate 550 and the second white plate 560.

The first white plate 550 may comprise a series of rectangular patches with different characteristics alternating with each other with a predetermined width. A patch (or an area) with a lower emissivity 551 and a patch with a higher emissivity 552 may alternate sequentially as shown in FIG. 5A. The lower emissivity may be an emissivity lower than a predetermined first emissivity threshold and the higher emissivity may be an emissivity higher than a predetermined second emissivity threshold.

There may be many values for both the first and second emissivity thresholds. For example, the first emissivity threshold may be between 0.05 and 0.2 and the second emissivity threshold may be between 0.6 and 0.85.

For example, the patches with lower emissivity 551 may be made of rough aluminum and in this case the emissivity may be 0.07 and the patches with higher emissivity 552 may be made of anodized aluminum and the emissivity in this case may be 0.77.

In this disclosure, substantially high emissivity may mean an emissivity higher than the second emissivity threshold and substantially low emissivity may mean an emissivity lower than the first emissivity threshold.

The second white plate 560 may comprise a series of rectangular patches spaced with slits with a predetermined width. A patch (or an area) with lower emissivity 561 and a slit 562 may alternate sequentially as shown in FIG. 5B. The emissivity of the patch 561 is the same as that of the patch 551 in FIG. 5A.

The first white plate 550 and the second white plate 560 may overlap each other.

For example, FIG. 5C illustrates a white wall 570 when only the patches with lower emissivity 551, 561 are exposed to face the wafer support 240. The second white plate 560 may be overlapped with the first white plate 550 and may be placed in front of the first white plate 200 in the direction of the wafer support 240. This overlapping movement can be done manually or by the wall moving mechanism 280.

In FIG. 5C, only patches with lower emissivity (551 & 561) may face wafer support when the slits 562 of the second white plate 560 may be placed on the lower emissivity patches 551 of the first white plate 550 so that the lower emissivity patches 551 of the first white plate 550 may be exposed and the lower emissivity patches 561 of the second white plate 560 may be placed over the higher emissivity patches 552 of the first white plate 550 so that the higher emissivity patches 552 of the first white plate 550 may not be exposed, attaining minimum emissivity (totally white wall). And in this case, the white wall 570 may absorb the heat from wafer support 240 the least so the temperature of wafer support 240 may stay constant longer.

FIG. 5D and FIG. 5E illustrate situations when the first white plate and second white plate are moved for different overlapping effect.

In FIG. 5D, the slits 212 of the second white plate 560 may be placed partially on the higher emissivity patches 552 (in this case half of the areas) of the first white plate 550 so that a resulting white wall 580 may absorb some more heat from wafer support 240 due to the partly exposed higher emissivity patches 552, reducing the temperature of wafer support a little more than in FIG. 5C.

In FIG. 5E, the white wall 590 may have maximum emissivity since the slits 562 of the second white plate 560 are placed right on the higher emissivity patches 552 of the first white plate 550 so that more heat could be absorbed compared to FIG. 5D.

FIG. 6A illustrates a first black plate 650 and FIG. 6B illustrates a second black plate 660 according to another embodiment of this disclosure. The black wall 220 (in FIG. 2) may comprise the first black plate 650 and the second black plate 660.

The first black plate 650 is the same as the first white plate 550 in FIG. 5A.

The second black plate 660 in FIG. 6B may comprise a series of rectangular patch with higher emissivity 661 spaced with slits. A patch (an area) with higher emissivity 661 and a slit 662 may alternate sequentially as shown in FIG. 6B. The emissivity of the patch 661 is the same as that of the patch 652 of FIG. 6A.

Just like the first white plate 550 and second white plate 560, the first black plate 650 and the second black plate 660 may overlap each other.

As illustrated in FIGS. 5A-5E and FIGS. 6A-6E, the width (interval) of each rectangular area (patch) are denoted as ‘d’. The width of each patch may be same for all patches or different for flexible control.

Generally, the width (d) of the patches could be between 5 mm and 25 mm for structural simplicity. However, between 5 mm and 10 mm may be desirable for operational conveniences.

The second black plate 660 may be overlapped with the first black plate 650 and it may be placed in front of the first black plate 650 to face wafer support 240.

FIG. 6E illustrates a black wall 690 when only the patches with higher emissivity 652, 661 of the first black plate 650 and the second black plate 660 are exposed to face the wafer support 240. Only patches with higher emissivity 652, 661 may face the wafer support 240 when the slits 662 of the second black plate 660 are placed on the higher emissivity patches 652 of the first black plate 650, attaining maximum emissivity (totally black wall). And in this case, the black wall 690 may absorb the heat from wafer support the most so the temperature of wafer support 240 may drop more rapidly than other occasions.

FIG. 6D illustrates when the slits 662 of the second black plate 660 are placed partially on the higher emissivity patches 652 of the first black plate 650. In this case, the temperature would be lower than the case of FIG. 6E. FIG. 6C illustrates when the slits 662 of the second black plate 660 are placed on the lower emissivity patches 651 of the first black plate 650. In this case, the temperature would be the lowest among the FIGS. 6C, 6D and 6E.

With the emissivity values given above (0.07 and 0.77 for different materials), the measured emissivity of FIG. 5C, FIG. 5D and FIG. 5E may be 0.07, 0.245 and 0.42, respectively, and those of FIG. 6C, FIG. 6D and FIG. 6E may be 0.42, 0.595 and 0.77, respectively.

In this respect, the emissivity of the white wall 230 may be always equal to or less than that of the black wall 220 and the emissivity of the white wall 230 may be substantially lower than that of the black wall 220 and the emissivity of the black wall 220 may be substantially higher than that of the white wall 230.

Additionally, a wall moving mechanism 280 may move the first/second black plates 650, 660 and the first/second white plates 550, 560. The wall moving mechanism 280 also may move each of the strips of black/white wall from expanded state (such as in FIG. 4A) to overlapped state (such as in FIG. 4B) and from the overlapped state to the expanded state.

The wall moving mechanism 280 may move plates (or strips) by pushing or pulling through linking materials 281, 282 that connect the mechanism 280 to each of the plates (550, 560, 650, 660) and to each of the strips (465a, 466a, 467a, 468a, 469a, 465b, 466b, 467b, 468b, 469b). In case the black wall or the white wall may have more than 1 (one) wall strips or plates, each of the linking material (281 and/or 282) may comprise more than 1 linking members which is configured to connect and link the wall moving mechanism 280 and each the strips or each of the plates.

The mechanism 280 can use electric motors and/or cam gears and/or latches and/or springs or any other methods which could be used to move something slowly and minutely.

In this disclosure, the wall moving mechanism 280 may handle both the black wall (strips or plates) and the white wall (strips or plates) however there could be more than one wall moving mechanisms so that one wall moving mechanism may control a black wall and the other wall moving mechanism may control a white wall.

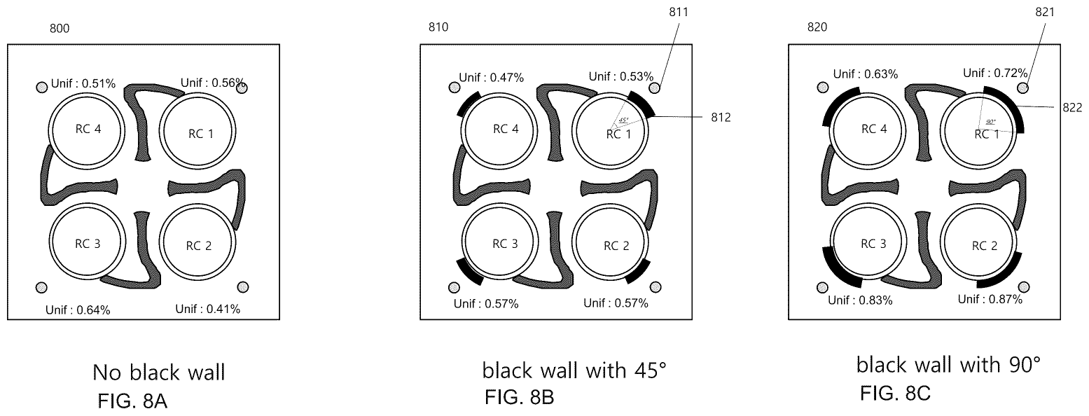

FIGS. 8A-8C illustrate testing results of the black walls in a four-chamber in an apparatus environment according to an embodiment of the present disclosure.

FIG. 8A illustrates a reference setting with no black wall, FIG. 8B illustrates a setting with a black wall with 45 degrees and FIG. 8C illustrates a setting with a black wall with 90 degrees of encirclement around the wafer support.

In FIG. 8A, temperature uniformity measured are 0.56%, 0.41%, 0.64% and 0.51% in chamber 1, chamber 2, chamber 3, and chamber 4, respectively, without black walls.

In FIG. 8B, temperature uniformity measured are 0.53%, 0.57%, 0.57% and 0.47% in chamber 1, chamber 2, chamber 3, and chamber 4, respectively, with 45 degrees of encirclement angle of black wall.

In FIG. 8C, temperature uniformity measured are 0.72%, 0.87%, 0.83%, 0.63% in chamber 1, chamber 2, chamber 3, and chamber 4, respectively, with 90 degrees of black wall encirclement angle.

As illustrated in the tests, the temperature uniformity gets better around 45° of black wall encirclement than no black wall but it gets worse when the black wall's encirclement angle is about 90°.

In FIG. 2, the encirclement angles are depicted in A1, A2 and A3.

It may be apparent that as the encirclement angle of black wall (A1) gets larger, the heat radiation could be absorbed more, rendering the temperature drop more rapidly. Also, as the encirclement angle of the white wall (A2) gets larger, the heat radiation from the wafer support 240 would be absorbed less, maintaining the temperature constantly longer.

The encirclement angle of the black wall (A1) and the encirclement angle of white wall (A2) can be calibrated to meet the wafer deposition uniformity purpose, and it can vary from 30° to 120°, preferably from 35° to 60° when considering the tests shown in FIGS. 8A-8C.

Also, a controller 180 in FIG. 1 may control the wall moving mechanism 280. The controller 180 and the wall moving mechanism 280 may be connected by wire or wirelessly and controller 180 can reserve the time and magnitude of the wall change (expanding/contracting in FIG. 4A and FIG. 4B's setting and overlapping in FIGS. 5A-5E and FIG. 6A-FIG. 6E's settings) and the mechanism 280 may execute the command of the controller accordingly.

The controller 180 may have input and output devices for getting inputs and for displaying the real-time status of black/white walls and even the status of temperature uniformity of each the chambers if equipped with sensors (not drawn).

Each of the width of the strips and the area in the plates may be same or different to meet the film uniformity purpose with respect to the environment of the apparatus or the chambers.

Also, the emissivity of the each of the areas of the plate in a black wall or each of the strips in a black wall may be same or different within the black wall.

For example, The emissivity of each of the strips 331 of FIG. 3B, of each of the areas 652 of FIG. 6A, of each of the areas 661 of FIG. 6B, of each of the strips (465a, 466a, 467a, 468a, 469a) of FIG. 4A, and of each of the strips (1031, 1032, 1033, 134, 135) of FIG. 10A may be the same or different if the second emissivity threshold condition is met for each of the areas or strips indicated above (i.e., the emissivity of any area or strip indicated is greater than the second emissivity threshold). The same is true for a white wall accordingly.

Also, the width of the areas and strips of a black wall or a white wall may be the same. However, they may be different from each other to meet the film uniformity purpose for different processing environments.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A wafer processing apparatus, comprising:
a wafer support provided with a heater for supporting and heating a wafer;
a chamber for enclosing and processing the wafer;
a showerhead for providing a gas into the chamber;
a pumping port for removing the gas from the chamber;
a black wall with a substantially high emissivity provided to the chamber where temperature is relatively higher than the other area and configured to partly encircle the wafer support; and
a white wall with a substantially low emissivity provided to the chamber where temperature is relatively lower than the other area and configured to partly encircle the wafer support.

2. The wafer processing apparatus according to claim 1, wherein,
the black wall comprises a plurality of black wall strips with a first predetermined width, and
the white wall comprises a plurality of white wall strips with a second predetermined width, wherein each of the plurality of black wall strips and each of the plurality of white wall strips are removable.

3. The wafer processing apparatus according to claim 1, further comprising:
a wall path configured to encircle the wafer support fully or partially.

4. The wafer processing apparatus according to claim 3, wherein
the black wall comprises a plurality of black wall strips, each of the plurality of black wall strips equipped with a bonding part which is used to connect it to a neighboring black wall strip; and
the white wall comprises a plurality of white wall strips, each of the plurality of white wall strips equipped with a bonding part which is used to connect it to a neighboring white wall strip, and
wherein the each of the black wall strips and each of the white wall strips configured to be placed on the wall path, and the each of the black wall strips and each of the white wall strips further configured to slide along the wall path between an expanded state and a contracted state.

5. The wafer processing apparatus according to claim 3, wherein
the black wall comprises a first black plate and a second black plate; and
the white wall comprises a first white plate and a second white plate,
wherein the first black plate comprises a first area with a first emissivity lower than a first emissivity threshold and a second area with a second emissivity higher than a second emissivity threshold, the first area and the second area being alternately arranged by a predetermined interval and,
the second black plate comprises a third area with a third emissivity higher than the second emissivity threshold and a slit, the third area and the slit being alternately arranged by the predetermined interval, and wherein
the first white plate comprises a fourth area with a fourth emissivity lower than the first emissivity threshold and a fifth area with a fifth emissivity higher than the second emissivity threshold, the fourth area and the fifth area being alternately arranged by a preselected interval; and
the second white plate comprises a sixth area with a sixth emissivity lower than the first emissivity threshold and a slit, the sixth area and the slit being alternately arranged by the preselected interval,
wherein the first black plate and/or the second black plate configured to slide on the wall path sideways, and
the first white plate and/or the second white plate configured to slide on the wall path sideways.

6. The wafer processing apparatus according to claim 3, wherein
a plurality of first rotatable rails configured to be placed in a first partial wall path, and
a plurality of black wall strips configured to be bound to the plurality of the first rotatable rails,
wherein the plurality of first rotatable rails configured to rotate in clockwise or counterclockwise direction to arrange the plurality of black wall strips into a state between an expanded state and a contracted state.

7. The wafer processing apparatus according to claim 6, wherein
a plurality of second rotatable rails which are rotatable configured to be placed in a second partial wall path,
a plurality of white wall strips configured to be bound to the plurality of the second rotatable rails,
and wherein the plurality of second rotatable rails configured to rotate in clockwise or counterclockwise direction, respectively, to arrange the plurality of the white wall strips into a state between an expanded state and a contracted state.

8. A wafer processing apparatus, comprising:
a wafer support provided with a heater for supporting and heating a wafer;
a chamber for enclosing and processing the wafer;
a showerhead for providing a gas into the chamber;
a pumping port for removing the gas from the chamber;
a black wall with a substantially high emissivity provided to the chamber where temperature is relatively higher than the other area and configured to partly encircle the wafer support;
a white wall with a substantially low emissivity provided to the chamber where temperature is relatively lower than the other area and configured to partly encircle the wafer support;
a wall path configured to encircle the wafer support fully or partially; and
a wall moving mechanism configured to move the black wall and the white wall along the wall path.

9. The wafer processing apparatus according to claim 8, further comprising:
a linking material configured to link the wall moving mechanism and the black wall, and further configured to link the wall moving mechanism and the white wall.

10. The wafer processing apparatus according to claim 9, wherein
the black wall comprises a plurality of black wall strips with a predetermined width, each of the plurality of black wall strips equipped with a bonding part which is used to connect it to a neighboring black wall strip; and
the white wall comprises a plurality of white wall strips with another predetermined width, each of the plurality of white wall strips equipped with a bonding part which is used to connect it to a neighboring white wall strip, wherein
the linking material comprises a plurality of linking members, wherein the plurality of linking members configured to link each of the plurality of black wall strips to the wall moving mechanism and further configured to link each of the plurality of the white wall strips to the wall moving mechanism, wherein
the wall moving mechanism configured to pull and/or push the plurality of the linking members to arrange the plurality of the black wall strips and/or the plurality of the white wall strips into a state between an expanded state and a contracted state.

11. The wafer processing apparatus according to claim 9, wherein
the black wall comprises a first black plate and a second black plate, and
the white wall comprises a first white plate and a second white plate,
wherein the first black plate comprises a first area with a first emissivity lower than a first emissivity threshold and a second area with a second emissivity higher than a second emissivity threshold, the first area and the second area being alternately arranged by a predetermined interval and,
the second black plate comprises a third area with a third emissivity higher than the second emissivity threshold and a slit, the third area and the slit being alternately arranged by the predetermined interval, and
wherein the first white plate comprises a fourth area with a fourth emissivity lower than the first emissivity threshold and a fifth area with a fifth emissivity higher than the second emissivity threshold, the fourth area and the fifth area being alternately arranged by a preselected interval; and
the second white plate comprises a sixth area with a sixth emissivity lower than the first emissivity threshold and a slit, the sixth area and the slit being alternately arranged by the preselected interval, and
wherein the linking material comprises four linking members, wherein each of the linking members are configured to link the wall moving mechanism and the first black plate, the second black plate, the first white plate and the second white plate, respectively, and wherein
the wall moving mechanism configured to pull and/or push the linking members to arrange the first and second black plate and the first and second white plate to change total emissivity for each of the black wall and the white wall.

12. The wafer processing apparatus according to claim 8, wherein
a plurality of first rotatable rails which are rotatable configured to be placed in a first partial wall path, and
a plurality of black wall strips configured to be bound to the plurality of the first rotatable rails,
and wherein the wall moving mechanism is further configured to rotate each of the plurality of the first rotatable rails in clockwise or counterclockwise direction, respectively, to arrange the black wall strips into a state between an expanded state and a contracted state.

13. The wafer processing apparatus according to claim 12, wherein
a plurality of second rotatable rails which are rotatable configured to be placed in a second partial wall path, and
a plurality of white wall strips configured to be bound to the plurality of the second rotatable rails,
and wherein the wall moving mechanism is further configured to rotate each of the plurality of the second rotatable rails in clockwise or counterclockwise direction, respectively, to arrange the white wall strips into a state between an expanded state and a contracted state.

14. A wafer processing apparatus, comprising:
a wafer support provided with a heater for supporting and heating a wafer;
a chamber for enclosing and processing the wafer;
a showerhead for providing a gas into the chamber;
a pumping port for removing gas from the chamber;
a black wall with a substantially high emissivity provided to the chamber where temperature is relatively higher than the other area and configured to partly encircle the wafer support;
a white wall with a substantially low emissivity provided to the chamber where temperature is relatively lower than the other area and configured to partly encircle the wafer support;
a wall path configured to encircle the wafer support;
a wall moving mechanism configured to move the black wall and the white wall along the wall path; and
a controller configured to control the wall moving mechanism by at least one of a wired connection or a wireless connection.

15. The wafer processing apparatus according to claim 14, further comprising:
a linking material configured to provide a link between the wall moving mechanism and the black wall and a link between the wall moving mechanism and the white wall.

16. The wafer processing apparatus according to claim 15, wherein
the black wall comprises a plurality of black wall strips with a predetermined width, each of the plurality of black wall strips equipped with a bonding part which is used to connect it to a neighboring black wall strip; and
the white wall comprises a plurality of white wall strips with another predetermined width, each of the plurality of white wall strips equipped with a bonding part which is used to connect it to a neighboring white wall strip,
wherein the linking material comprises a plurality of linking members, and
wherein the plurality of linking members configured to link each of the plurality of black wall strips to the wall moving mechanism and further configured to link each of the plurality of the white wall strips to the wall moving mechanism, and
the controller configured to control the wall moving mechanism to pull and/or push the plurality of the linking members to arrange the plurality of the black wall strips and/or the plurality of the white wall strips into a state between an expanded state and a contracted state.

17. The wafer processing apparatus according to claim 15, wherein
the black wall comprises a first black plate and a second black plate, and
the white wall comprises a first white plate and a second white plate, and wherein
the first black plate comprises a first area with a first emissivity lower than a first emissivity threshold and a second area with a second emissivity higher than a second emissivity threshold,
the first area and the second area alternately arranged by a predetermined interval; the second black plate comprises a third area with a third emissivity higher than the second emissivity threshold and a slit, the third area and the slit alternately arranged by the predetermined interval; and
the first white plate comprises a fourth area with a fourth emissivity lower than a first emissivity threshold and a fifth area with a fifth emissivity higher than a second emissivity threshold alternately arranged by a preselected interval; and
the second white plate comprises a sixth area with a sixth emissivity lower than the first emissivity threshold and a slit, the sixth area and the slit alternately arranged by the preselected interval, and
wherein the linking material comprises four linking members, wherein each of the linking members are configured to link the wall moving mechanism and the first black plate, the second black plate, the first white plate and the second white plate, respectively, and wherein
the controller is further configured to control the wall moving mechanism to pull and/or push the linking members to arrange the first and second black plate and the first and second white plate to change total emissivity for each of the black wall and the white wall.

18. The wafer processing apparatus according to claim 14, wherein
a plurality of first rotatable rails configured to be placed along a first partial wall path, and
a plurality of black wall strips configured to be bound to the plurality of the first rotatable rails,
and wherein the controller configured to control the wall moving mechanism to rotate each of the plurality of the first rotatable rails in clockwise or counterclockwise direction, respectively, to arrange the black wall strips into a state between an expanded state and a contracted state.

19. The wafer processing apparatus according to claim 18, wherein
a plurality of second rotatable rails configured to be placed along a second partial wall path, and
a plurality of white wall strips configured to be bound to the plurality of the second rotatable rails,
and wherein the controller configured to control the wall moving mechanism to rotate each of the plurality of the second rotatable rails in clockwise or counterclockwise direction, respectively, to arrange the white wall strips into a state between an expanded state and a contracted state.
